(19) United States
(12) Patent Application Publication
(10) Pub. No.: US 2017/0083134 A1
(43) Pub. Date: Mar. 23, 2017

(54) INTERACTIVE DISPLAYABLE DEVICE

(71) Applicant: Thomas Evans, Aurora, CO (US)

(72) Inventor: Thomas Evans, Aurora, CO (US)

(21) Appl. No.: 14/858,496

(22) Filed: Sep. 18, 2015

(51) Int. Cl. G06F 3/041; H05K 3/46; G06F 1/16

(52) U.S. Cl. CPC G06F 3/0412; G06F 3/0416; G06F 1/1688; H05K 3/46; G06F 2203/04103

(57) ABSTRACT

Non-limiting examples of the present disclosure comprise an exemplary displayable device. An exemplary interactive displayable device may comprise a structure and a programmable touch circuit board. The structure may comprise a first surface where at least one portion of the front surface is covered with a layer of conductive paint. The first surface has one or more apertures filled with the conductive paint. The programmed touch circuit board is mounted on a second surface of the structure. At least one wire places a node of the programmed touch circuit board in contact with the conductive paint. Other examples of displayable devices as well as methods for producing exemplary displayable devices are also described.

### BACKGROUND

Traditionally, artwork is static and non-interactive. Such artwork is typically displayed with a “look but do not touch” mindset. As technology advances, artists are afforded more opportunities to creatively develop unique pieces of artwork as well as new methods for creating such unique artwork. It is with respect to this general environment that aspects of the present technology disclosed herein have been contemplated.

### SUMMARY

Non-limiting examples of the present disclosure describe methods for producing exemplary displayable devices. Conductive paint is applied to at least a first surface of a structure and within one or more apertures of the structure. A processing unit may be mounted to a portion of the structure. At least one node of the processing unit may be connected with the applied conductive paint. The node of the processing unit may be programmed. As a result, when power is supplied to the exemplary displayable device and a touch input is received on the first surface, content may be output by the interactive displayable device.

Other non-limiting examples comprise an exemplary interactive displayable device. An exemplary interactive displayable device may comprise a structure and a programmable touch circuit board. The structure may comprise a first surface where at least one portion of the front surface is covered with a layer of conductive paint. The first surface has one or more apertures filled with the conductive paint. The programmed touch circuit board is mounted on a second surface of the structure. At least one wire places a node of the programmed touch circuit board in contact with the conductive paint.

Additional non-limiting examples of a displayable device may comprise a plurality of components. An exemplary displayable device may comprise a structure, a programmed processing, an amplifier, a speaker and a storage device. The structure comprises a first surface made of canvas, wherein at least one portion of the first surface is covered with a layer of conductive paint and wherein the first surface has a first set of one or more apertures filled with the conductive paint and a second set of one or more apertures. The programmed processing unit is mounted on a second surface of the structure. At least one wire places a node of the programmed processing unit in contact with the conductive paint. The amplifier is mounted on the second surface of the structure. The amplifier comprises a power source and is connected with the programmed processing unit. The speaker is mounted on the second surface of the structure in alignment with the second set of one or more apertures. The speaker may be connected with the amplifier. The storage device is connected with the programmed processing unit. The storage device stores content that is accessible by the programmed processing unit in response to touch received on the portion of the structure that is covered by the conductive paint. As an example, the programmed processing unit is a programmed touch circuit board. In additional examples, a third surface may cover the second surface. The third surface may have one or more apertures, where conductive paint is filled in the one or more apertures and one or more portions of the third surface. In such an additional example, more than one surface of an exemplary displayable device may be interactive.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following figures. As a note, the same number represents the same element or same type of element in all drawings.

FIG. 1A is an exploded diagram of layers of an exemplary displayable device as described herein.

FIG. 1B is a top view of a structure of an exemplary displayable device as described herein.

FIG. 1C is a top view of a portion of a structure of an exemplary displayable device as described herein.

FIG. 1D illustrates an interaction between an exemplary displayable device and another processing device as described herein.

FIG. 1E is a top view of a front surface of a structure for an exemplary displayable device as described herein.

FIG. 2 is an illustration depicting an interaction between a user and an exemplary displayable device as described herein.

FIG. 3 illustrates interaction between components of an exemplary displayable device as described herein.

FIG. 4 illustrates one example of a suitable operating environment that may interact with an exemplary display device as described herein.

FIG. 5 illustrates an exemplary method for producing a displayable device as described herein.

### DETAILED DESCRIPTION

Non-limiting examples of the present disclosure describes a displayable device that comprises a structure connected with electronic components in a manner that enables one or more surfaces of the structure to become interactive. As an example, the displayable device introduces elements that enable a user to interact with the displayable device while still appearing to look like traditional static artwork such as a painting, installation art, etc. In examples, conductive paint is utilized as an interface for user, to trigger programmed actions of a processing unit installed within the displayable device. As an example, the processing unit may be a touch circuit board. Furthermore, methods are described for creation of exemplary interactive displayable devices.

A plurality of technical effects are achieved over traditional artwork including but not limited to: interactivity by a device that comprises electrical components to enable an interactive experience with a user beyond physical aesthetics, ability to engage users with disabilities (e.g., vision impaired), ability to make interactive multiple surfaces of a displayable device, ability to re-program an interactive displayable device to manipulate output of content, and an ability to connect to other processing devices, among other examples.

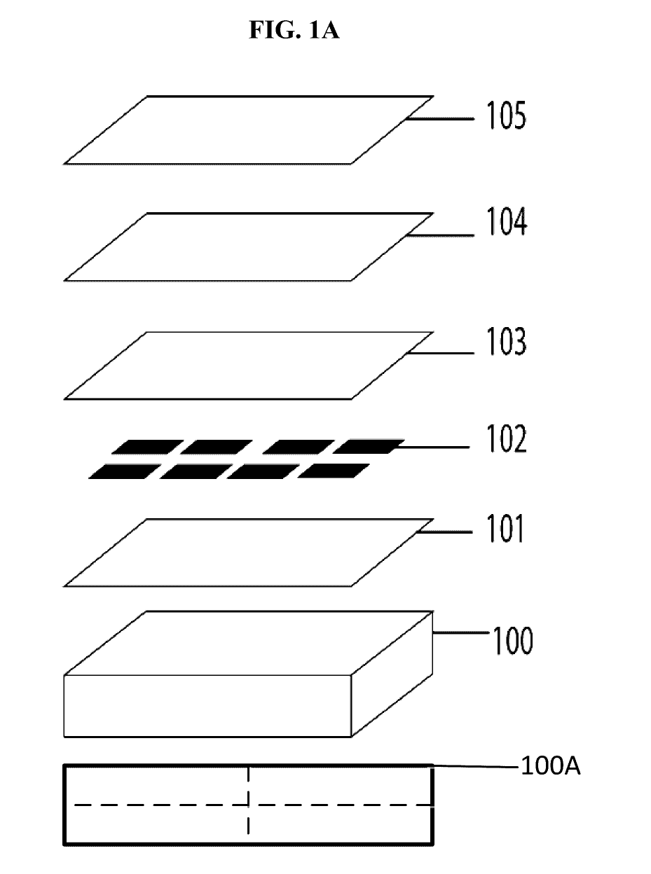

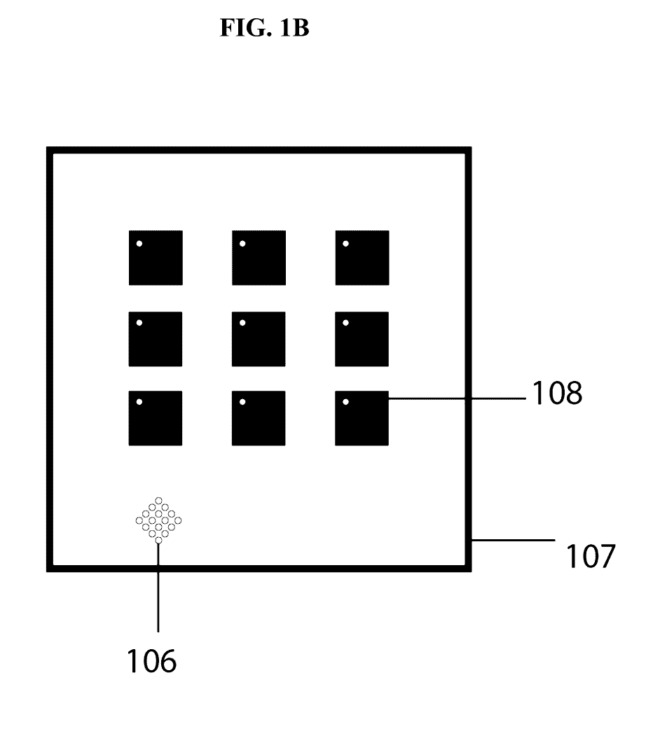

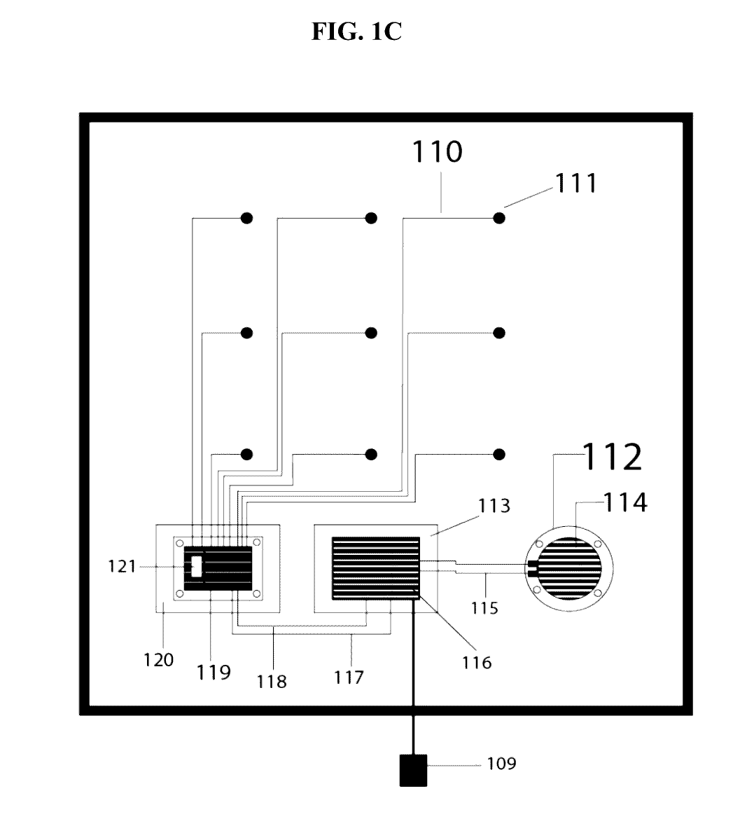

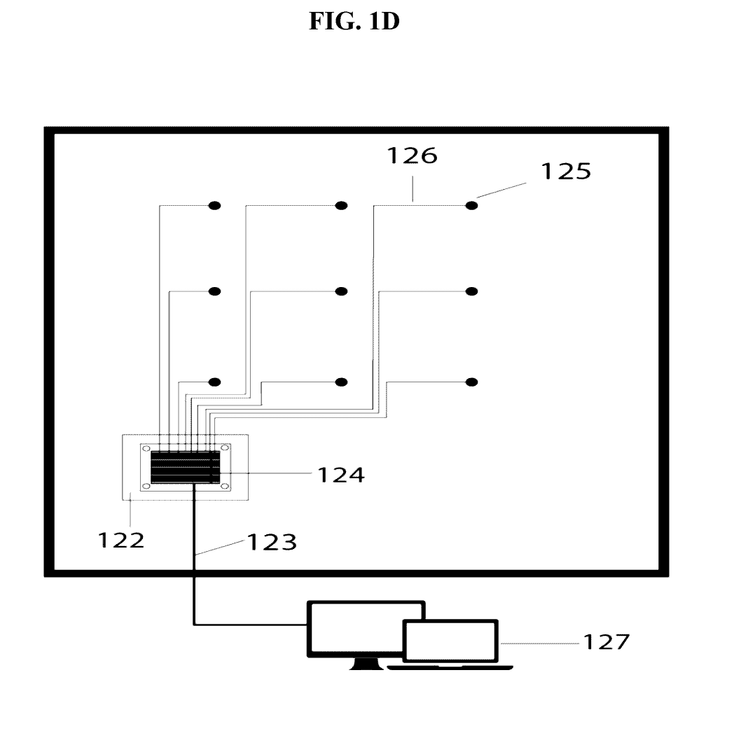

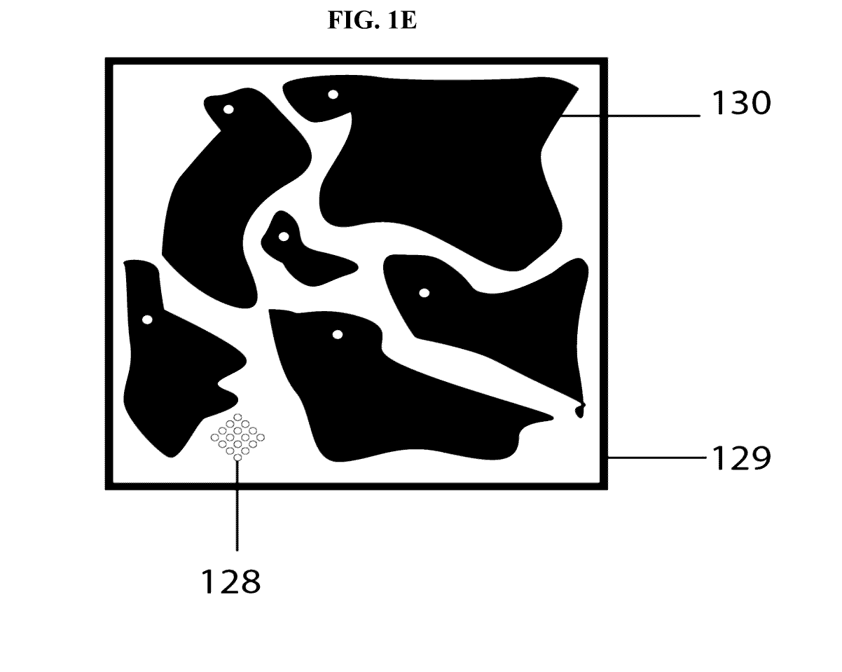

FIG. 1A is an exploded diagram of layers of an exemplary displayable device as described herein. An exemplary displayable device may be utilized for any purpose including as displayable artwork. An exemplary displayable device may comprise a plurality of components as described throughout this disclosure. The exemplary displayable device may comprise a structure, for example that acts as a base layer for the displayable device. A structure may be framework that has one or more surfaces and provides support for an exemplary displayable device. In some examples, surfaces of an exemplary displayable device may be constructed upon a frame 100A shown in FIG. 1A. As an example, one or more surfaces (e.g., painting surfaces) may be stretched across frame 100A to provide space upon the structure to add artwork. For example canvas/panel canvas 100 may be a layer built upon frame 100A. In other examples, an exemplary structure may comprise a canvas or panel canvas 100 that is molded in a particular shape. In cases where the panel canvas 100 is molded in rigid structural orientation, a frame 100A may be optional. In some cases, portions of frame 100A may be added to a panel canvas 100 to enable additional structural elements or dimensions to be added to an exemplary structure. That is, the exemplary structure is scalable and extensible. Portions of the structure, comprising the panel canvas 100 and/or frame 100A, may be made out of any material including but not limited to: wood, compressed composite material, metal, concrete, stone, plastic, etc. One skilled in the art should recognize that materials may be used to construct portions of the structure in any shape that may be desired for design purposes.

Additional layers may be added/built upon base structural elements such as canvas/panel canvas 100 and/or frame 100A. As identified above, canvas or panel canvas 100 provides one or more surfaces upon which paint, primer, objects, etc. may be applied. FIG. 1A illustrates layer 101, which is applicable on the canvas/panel canvas 100 layer. Layer 101 is a first primer layer that may be used to prepare the canvas/panel canvas 100 for application of paint or any other substance. Primer is a substance used as a preparatory coat on previously unpainted wood, metal, or canvas, especially to prevent the absorption of subsequent layers of paint, for example. One skilled in the art should recognize that any type of primer may be used for first primer layer 101. As an example, first primer layer 101 may comprise acrylic primer, gesso primer, acrylic gesso, etc. As an example, the first primer layer 101 can be applied in any manner including brush, spray, machine, application by body parts (e.g., fingers, hands, and feet), etc.

Furthermore, additional layers may be added upon the first primer layer 101. As an example a conductive paint layer 102 may be added over the first primer layer 101. The conductive paint layer 102 comprises conductive paint. Conductive paint (or electric paint) is any paint substance that is electrically conductive. Conductive paint acts as insulation or to create multi-layer circuitry over a wide variety of different materials including one or more layers of an exemplary structure. One skilled in the art, should. recognize that a number of conductive paint layers 102 may be added to an exemplary structure where a layer may comprise painting any portion of the exemplary structure. In examples, the conductive paint layer 102 may be arranged in any way to achieve an intended design purpose. As an example, the conductive paint layer 102 can be applied in any manner including brush, spray, machine, application by body parts (e.g., fingers, hands, and feet), etc.

In examples, a second primer layer 103 may be added on top of the conductive paint layer 102 to prepare a canvas (or other material of the structure upon which the conductive paint is applied) for substance and actions such as painting. In examples, the same (or different) primer may be used that was applied in the first primer layer 101. As an example, the second primer layer 103 can be applied in any manner including brush, spray, machine, application by body parts (e.g., fingers, hands, and feet

A substance layer 104 may be added on top of the second primer layer 103. As an example, the substance layer 104 represents a layer upon which a substance may be added for design purposes. For instance, an artist may apply paint to substance layer 104 as intended expression or representation. One skilled in the art should recognize that any substance may be added to substance layer 104 including but not limited to: oil and acrylic paint, paint, ink or writing, airbrush, colors, spray paint, house paint, objects, etc. As an example, the substance layer 104 can be applied in any manner including brush, spray, machine, application by body parts (e.g., fingers, hands, and feet), etc,

In examples, a sealant layer 105 may be added upon the substance layer 104. The sealant layer 105 may comprise any clear coat substance that is used to protect the previous applied layers (including the conductive paint layer 102 and the. substance layer 104) from touch, among other examples. As an example, the sealant layer 105 can be applied in any manner including brush, spray, machine, application by body parts (e.g., fingers, hands, and feet), etc. Sealants may comprise clear coat sealant, polycrylic, varnish, etc., among other examples.

By applying multiple layers to one or more surfaces of an exemplary displayable device can be transformed in a manner that not only protects the conductive paint layers but also enables a surface of a displayable device to be configured to guide users for interaction with the displayable device. Based on this disclosure, one skilled in the art should recognize that the layers described in FIG. 1A can be arranged in any way. Additionally, in alternative examples, each layer of FIG. 1A may comprise one or more additional layers.

FIG. 1B is a top view of a structure of an exemplary displayable device as described herein. In examples, FIG. 1B illustrates an exemplary surface of an interactive displayable device. For instance, FIG. 1B illustrates surface (e.g., a top surface, front surface, etc.) of an interactive display device that is presentable to users/viewers. As identified above, one skilled in the art should recognize that more than one surface may be interactive for an exemplary interactive displayable device. For instance, an exemplary interactive displayable device may have two or more surfaces similar to that as shown in FIG. 1B.

As shown in FIG. 1B, a set of apertures 106 may be drilled through a surface of an exemplary displayable holes. In examples, the set of apertures 106 may comprise one or more holes and may be used to enable sound, light, objects, images, etc. that are incorporated within the interactive displayable device to project through the set of apertures 106. As an example, the set of apertures 106 may be a set of speaker holes that may enable sound to pass through a surface of the interactive displayable device and project towards an audience. For instance, electrical components such as one or more processing units/device, speakers, amplifiers, televisions, among other examples. The set of apertures 106 may be produced by any process including but not limited to: drilling, poking, scraping, burning, etc. One skilled in the art should recognize devices that may be used to produce the set of apertures 106. Placement of the set of apertures 106 may be on any portion of a surface of the interactive displayable device. In some examples, a plurality of sets of apertures 106 may be incorporated within an exemplary interactive displayable device.

Also shown in FIG. 1B is a surface 107. A surface 107 is a presentable layer of an interactive displayable device. One or more components of the interactive displayable device including but not limited to the set of apertures 106 and portions of conductive paint 108, as examples, may be incorporated within or able to be applied to surface 107. Surface 107 may comprise any material suitable for application of substances such as paint, ink, etc. As an example, surface 107 may be made of canvas such as canvas/panel canvas 100 described in FIG. 1A.

FIG. 1B further illustrates portions of conductive paint 108 applied to surface 107. In examples, one or more portions of conductive paint may be applied to surface 107. The portions of conductive paint 108 may comprise conductive paint as described in the description of FIG. 1A. Portions of conductive paint 108 may comprise one or more applications of conductive paint to surface 107. The portions of conductive paint 108 may be applied in any fashion such as by application of a paint brush, body parts, tools/devices, spray, among other examples. Further, portions of conductive paint 108 may be designed in any way and any shape in application to surface 107.

FIG. 1C is a top view of a portion of a structure of an exemplary displayable device as described herein. An exemplary structure may act as a base layer for the displayable device. A structure may be framework that has one or more surfaces and provides support for an exemplary displayable device. FIG. 1C illustrates a view of a portion of the structure, for example, a back portion of the structure that may or may not be viewable to a viewer. However, FIG. 1C is not limited to representing a back portion of the structure. In one example, the structure may resemble a painting where a front portion is displayable to a viewer and a back portion is obstructed from view, for example, by a wall, lack of line of sight, etc. In other examples, the portion of the structure shown in FIG. 1C may be covered by one or more additional portions or surfaces of an exemplary structure. For instance, an exemplary structure may be extensible where additional portions can be added. In one example, components described herein including in FIG. 1C, may be covered by another surface (e.g., framework and canvas or panel canvas) to appear as double-sided artwork where a first surface may comprise a surface with one or more layers of paint and a second surface may also comprise one or more layers of paint. In such an example, conductive paint may be applied to the one or more surfaces and one or more components of FIG. 1C may come into contact with the conductive paint to enable the one or more surfaces to become interactive. In one example, the canvas surface is configured as a focus point that is not replaceable. This may provide a benefit that enables an interactive displayable device to be mountable to another structure or surface such as a wall, ceiling, floor, etc.

FIG. 1C comprises a power source 109 that may be used to supply power to an exemplary interactive displayable device. Electrical components of an interactive displayable device are connected in order to produce power to provide output. The power source 109 may be a power source for any of the electrical components. As an example, the power source 109 may be a power source for an amplifier, for instance an AC/DC adapter or AC/DC converter. In other examples, the power source may be another processing device such as a computer, tablet, laptop, etc. When such a processing device is powered on, power may be supplied to the interactive displayable device.

FIG. 1C further illustrates wiring 110 that may be used to connect conductive paint to a processing unit 119. In one example, twenty-two (22) gauge wire may be used. However, one skilled in the art should recognize that any wiring may be used to place portions of conductive paint in contact with a node of a processing unit (such as a touch circuit board, among other examples). As shown in FIG. 1C, the wiring 110 connects portions of conductive paint 111 to at least one processing unit 119. The portions of conductive paint 111 utilize conductive paint as previously described in description of the present disclosure. In examples, portions of conductive paint 111 may be pushed through or applied on first surface of the structure to be provided on another surface of the structure. In such an example, wiring 110 would not need to protrude through a first surface of the displayable device so as to avoid being exposed to a viewer/user. The apertures may be covered with paint to conceal the apertures and provide a seamless viewing surface for a user. In examples, apertures may be created to enable the conductive paint to pass from one portion of structure to another. Portions of conductive paint 111 may be applied through apertures of the structure in any method including but not limited to brushing, spraying, shooting, using tools/devices (e.g., conductive paint applicator such as conductive paint pen, etc.).

The processing unit 119 is any electronic circuitry that is programmable and may carry out programmed instructions, for example, by performing arithmetic, logical, control and input/output (I/O) operations specified by the instructions. The processing unit 119 may be connected with the power source 109 to enable processing operations to be performed in order to execute intended operations. In one example, when a user touches one or more of the portions of conductive paint 111, the wiring 110 may transmit a signal to the processing unit 119. In that example, the wiring 110 may be connected with one or more nodes of the processing unit 119 that is programmed to execution specific instructions and/or operations to produce an output. For instance, a user may touch a surface of the interactive displayable device at a portion of conductive paint 111, resulting in output of content such as sound/audio, visual content, light, etc. In one example, the processing unit may be a touch circuit board that is programmable. The touch circuit board may be programmed, where nodes of the touch circuit board may perform specific operations and output content, for example, in response to detection of a touch on a surface of an interactive displayable device. In examples, the processing unit 119 may be mounted, to a portion of the structure using a processing unit mount 120 that is comprised of any material. In one example, the processing unit mount 120 may be made of metal. However, the processing unit mount 120 may be configured in any way and made of any material that is strong enough to secure the processing unit 119 to the structure. In examples, the processing unit mount 120 may comprise one or more components such as metal/wood portions and means to secure such portions (e.g., screws, nails, staples, clips, glue, etc.) to the structure.

In examples, the processing unit 119 may interface with a storage device 121 that may store content which may be triggered for output based on processing operations performed by the interactive displayable device. In one example, the storage device 121 is any physical external device that may be attached to, connected with or inserted into the processing unit 119. In other examples, the storage device may be a memory or programmed portion of the processing unit 119 that is configurable to store instructions for execution of processing operations. The processing unit may be programmed to read content from a storage device 121. Storage device 119 may be any volatile or non-volatile memory. For instance, the processing unit 119 may be programmable using any applications and executing in any programming languages. For instance, a processing device may be connected to the processing unit 119 to enable programming and customizable configuration of the processing unit 119. The processing unit 119 may be programmed to read content from a storage device 119 such as a memory card (e.g., secure digital (SD) card or storage media). In one example, audio files may be stored on an SD card that is inserted into a processing unit 119 such as a programmed touch circuit board.

An exemplary interactive displayable device may further comprise other electrical components such as speaker 114. The speaker 114 may be connected with one or more other electrical components and used to output content such as audio content to provide an interactive dimension of the displayable device. In examples, the speaker 114 receives transmitted signals from the processing unit 119 for output of the content. In one example, the speaker is installed/mounted on a back portion of the structure so as to be hidden from view of a user. For instance, a set of apertures may be provided on a front surface of an interactive displayable device, where the apertures are aligned with placement of the speaker on a back portion of the structure, thus enabling sound to be emitted from the speakers in an un-obstructed manner. In other examples, the speaker 114 may be mounted on the structure in plain view of the user. For instance, the speaker 114 may be used in an expression of art in addition to providing function and utility for the interactive displayable device. In examples, the speaker 114 may be mounted to a portion of the structure using a speaker mount 112 that is comprised of any material. In one example, the speaker mount 112 may be made of metal. However, the speaker mount 112 may be configured in any way and made of any material that is strong enough to secure the speaker 114 to the structure. In examples, the speaker mount 112 may comprise one or more components such as metal/wood portions and means to secure such portions (e.g., screws, nails, staples, clips, glue, etc.) to the structure.

In examples, the speaker 114 may be connected with other electrical components such as an amplifier 116. An amplifier 116 may be used to connect the processing unit 119 with the speaker 114. The amplifier 116 may be any electronic device that is capable of increasing the amplitude of electrical signals output from the processing unit 119, for example, to generate sound reproduction that is output from the speaker 114. In one example, the storage device 121 may store audio files that can be processed by the processing unit 119 to send signals through the amplifier 116 to the speaker 114 for output. Any type of amplifier may be used for the amplifier 116. In one example, the amplifier is a forty (40) watt, multi-channel amplifier. In examples, the amplifier 116 may be mounted to a portion of the structure using an amplifier mount 113 that is comprised of any material. In one example, the amplifier mount 113 may be made of metal. However, the amplifier mount 113 may be configured in any way and made of any material that is strong enough to secure the amplifier 116 to the structure. In examples, the amplifier mount 113 may comprise one or more components such as metal/wood portions and means to secure such portions (e.g., screws, nails, staples, clips, glue, etc.) to the structure.

The speaker 114 may be connected with the amplifier 116 any electrical means including but not limited to a wire 115. In some examples, wire 115 may be the same material as wire 110 described above, However, any type of wiring may be used for wire 115. The amplifier 116 may be connected to the processing unit 119 by any electrical means. As an example the amplifier 116 is connected with the processing unit 119 using a cord/cable 117. In one example, the cord/cable 117 is a micro universal serial bus (USB) cable. However, one skilled in the art should recognize that the electrical connection may vary depending on the components used in the exemplary displayable device. As an example the amplifier 116 is further connected with the processing unit 119 using an auxiliary cable/cord 118 that may be used to transmit electronic signals for sound from the processing unit to the amplifier 116.

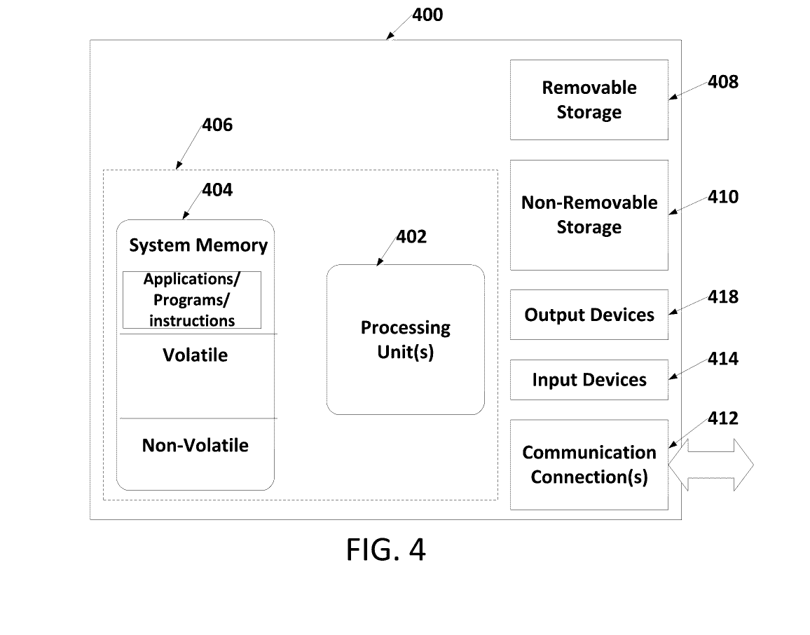

FIG. 1D illustrates an interaction between an exemplary displayable device and another processing device as described herein. Components of FIG. 1D may be similar to those shown and described in the description of FIG. 1C. For example, FIG. 1D comprises a processing unit such as a circuit board 123 that is mounted on a structure of an exemplary interactive displayable device. The circuit board 123 is connected to a surface/canvas of the structure to enable processing operations, for example via touch input received. The circuit board 123 is mounted to a portion of the structure, for example a surface, using a circuit board mount 122, similar to that described processing unit mount 120 described in FIG. 1C. Another example of conductive paint 125, like portions of conductive paint 111 of FIG. 1C, is again illustrated in FIG. 1D. Portions of the conductive paint 125 are connected to the circuit board 123 through electrical means such as wire(s) 126. FIG. 1D illustrates connection of another processing device 127 to an exemplary interactive displayable device. Further details of a processing device 127 are provided in the description of FIG. 4. FIG. 1D illustrates an electrical means for connecting the processing device 127 to the circuit board 123, for example a USB cord 123 such as a micro USB cord. However, one skilled in the art should recognize that cords or cables may not be required to connect a processing unit such as circuit board 123 with processing device 127. In examples, such as connection may be completed using wireless signals, infrared, Bluetooth, etc. The same can be said for any connection of the electrical components described herein. However, physical connections may be utilized to improve signal processing.

FIG. 1E is a top view of a front surface of a structure for an exemplary displayable device as described herein. A surface 129 of an interactive displayable device is shown in FIG. 1E. The surface 129 is any surface as previously described herein, for example a canvas or panel canvas. A set of one or more apertures 128 may be provided through a surface of a structure of an exemplary interactive displayable device. The apertures 128 may be used to allow sound to clearly transmit through a solid surface 129. As an example, a speaker may be aligned with the set of apertures 128 to output audio content through surface 129. Portions of conductive paint 130 are further illustrated on surface 129, providing yet another example of creativity using conductive paint. In examples, one or more layers of additional substance may be provided over the portions of conductive paint 130. For further detailed description, refer back to FIG. 1A.

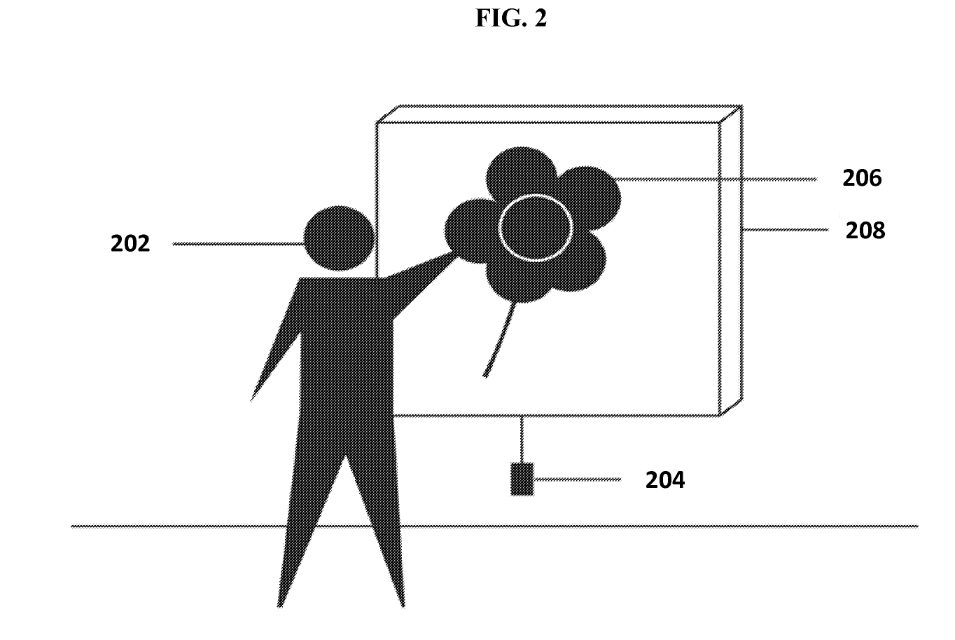

FIG. 2 is an illustration depicting an interaction between a user and an exemplary displayable device as described herein. As shown in FIG. 2, a user 202 may interact with an exemplary interactive displayable device through a sense such as touch. The user 202 may apply force to a surface/canvas 208 of the displayable device at a point where layers of substance 206 are applied to the surface/canvas 208. The layers of substance 206 may comprise at least one layer of conductive paint. In one example, power may be further provided to the interactive displayable device through a power source 204 such as an AC adapter connecting an electrical component (e.g., amplifier) to a source of power.

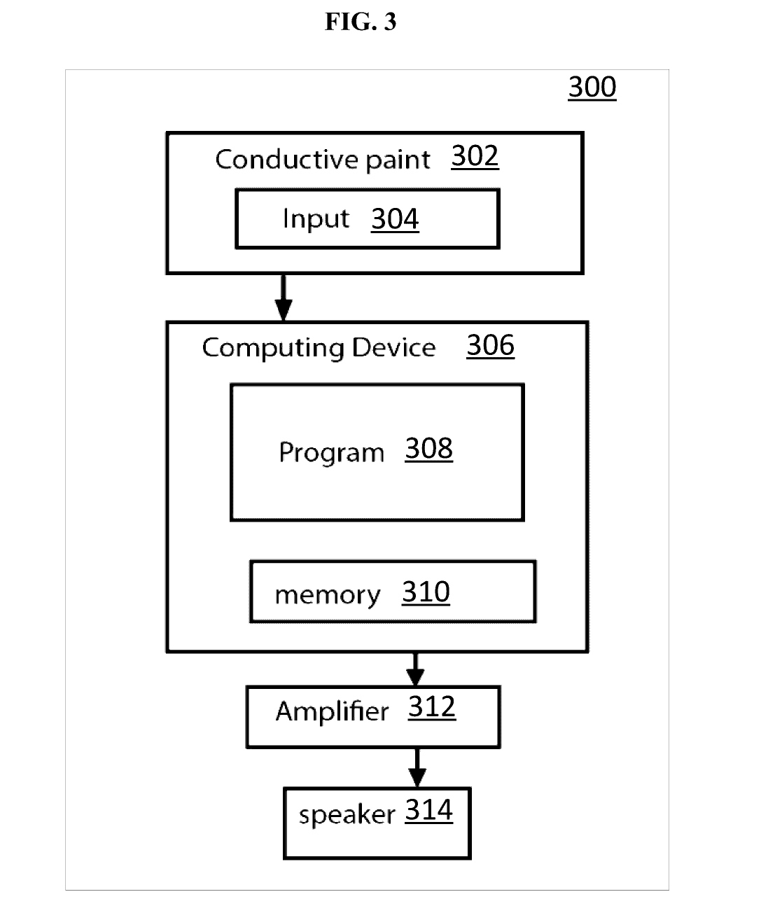

FIG. 3 illustrates interaction between components of an exemplary displayable device as described herein. One or more portions of conductive paint 302 may be triggered by received input 304. As an example, received input 304 may be touch applied to the portions of conductive paint 302, for example, by a user. An electrical signal may be transmitted from a portion of conductive paint 302 (through electrical means) to a computing device 306. The computing device 306 may be any device comprising one or more circuits or processors. A computer-readable program or instructions 308 may be stored in at least one memory 310 of the computing device 306. When an electrical signal is received at the computing device 306 from the conductive paint 302, one or more signals are transformed and output to an amplifier 312. Electrical signals are processed by the amplifier 312 and transmitted to a speaker 314. The speaker 314 may process received electrical signals and produce an output, such as audio.

FIG. 4 and the additional discussion in the present specification are intended to provide a brief general description of a suitable computing environment in which the present invention and/or portions thereof may be implemented. Although not required, the embodiments described herein may be implemented as computer-executable instructions, such as by program modules, being executed by a computer, such as a client workstation or a server. Generally, program modules include routines, programs, objects, components, data structures and the like that perform particular tasks or implement particular abstract data types. Moreover, it should be appreciated that the invention and/or portions thereof may be practiced with other computer system configurations, including hand-held devices, multi-processor systems, microprocessor-based or programmable consumer electronics, network PCs, minicomputers, mainframe computers and the like. The invention may also be practiced in distributed computing environments where tasks are performed by remote processing devices that are linked through a communications network. In a distributed computing environment, program modules may be located in both local and remote memory storage devices.

FIG. 4 illustrates one example of a suitable operating environment 400 in which one or more of the present embodiments may be implemented. This is only one example of a suitable operating environment and is not intended to suggest any limitation as to the scope of use or functionality. Other well-known computing systems, environments, and/or configurations that may be suitable for use include, but are not limited to, personal computers, server computers, hand-held or laptop devices, multiprocessor systems, microprocessor-based systems, programmable consumer electronics such as smart phones, network PCs, minicomputers, mainframe computers, distributed computing environments that include any of the above systems or devices, and the like. The operating environment 400 may be that of a processing device included within or connected with an exemplary interactive displayable device.

In its most basic configuration, operating environment 400 typically includes at least one processing unit 402 and memory 404. Depending on the exact configuration and type of processing device, memory 404 (storing, among other things, taste extraction components, taste curation components, taste tagging components, administrative components, and/or instructions to perform the methods disclosed herein) may be volatile (such as RAM), non-volatile (such as ROM, flash memory, etc.), or some combination of the two. This most basic configuration is illustrated in FIG. 4 by dashed line 406. Further, environment 400 may also include storage devices (removable, 408, and/or non-removable, 410) including, but not limited to, magnetic or optical disks or tape. Similarly, environment 400 may also have input device(s) 414 such as keyboard, mouse, pen, voice input, etc. and/or output device(s) 416 such as a display, speakers, printer, etc. Also included in the environment may be one or more communication connections, 412, such as LAN, WAN, point to point, etc.

Operating environment 400 typically includes at least some form of computer readable media. Computer readable media can be any available media that can be accessed by processing unit 402 or other devices comprising the operating environment. By way of example, and not limitation, computer readable media may comprise computer storage media and communication media. Computer storage media includes volatile and nonvolatile, removable and non-removable media implemented in any method or technology for storage of information such as computer readable instructions, data structures, program modules or other data. Computer storage media includes, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other non-transitory medium which can be used to store the desired information. Computer storage media does not include communication media.

Communication media embodies computer readable instructions, data structures, program modules, or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of the any of the above should also be included within the scope of computer readable media.

The operating environment 400 may be a single computer operating in a networked environment using logical connections to one or more remote computers. The remote computer may be a personal computer, a server, a router, a network PC, a peer device or other common network node, and typically includes many or all of the elements described above as well as others not so mentioned. The logical connections may include any method supported by available communications media. Such networking environments are commonplace in offices, enterprise-wide computer networks, intranets and the Internet.

The different aspects described herein may be employed using software, hardware, or a combination of software and hardware to implement and perform the systems and methods disclosed herein. Although specific devices have been recited throughout the disclosure as performing specific functions, one of skill in the art will appreciate that these devices are provided for illustrative purposes, and other devices may be employed to perform the functionality disclosed herein without departing from the scope of the disclosure.

As stated above, a number of program modules and data files may be stored in the system memory 404. While executing on the processing unit 402, program modules 408 (e.g., applications, Input/Output (I/O) management, and other utilities) may perform processes including, but not limited to, one or more of the stages of the operational methods described herein.

Furthermore, examples of the invention may be practiced in an electrical circuit comprising discrete electronic elements, packaged or integrated electronic chips containing logic gates, a circuit utilizing a microprocessor, or on a single chip containing electronic elements or microprocessors. For example, examples of the invention may be practiced via a system-on-a-chip (SOC) where each or many of the components illustrated in FIG. 4 may be integrated onto a single integrated circuit. Such an SOC device may include one or more processing units, graphics units, communications units, system virtualization units and various application functionality all of which are integrated (or “burned”) onto the chip substrate as a single integrated circuit. When operating via an SOC, the functionality described herein may be operated via application-specific logic integrated with other components of the operating environment 400 on the single integrated circuit (chip). Examples of the present disclosure may also be practiced using other technologies capable of performing logical operations such as, for example, AND, OR, and NOT, including but not limited to mechanical, optical, fluidic, and quantum technologies. In addition, examples of the invention may be practiced within a general purpose computer or in any other circuits or systems.

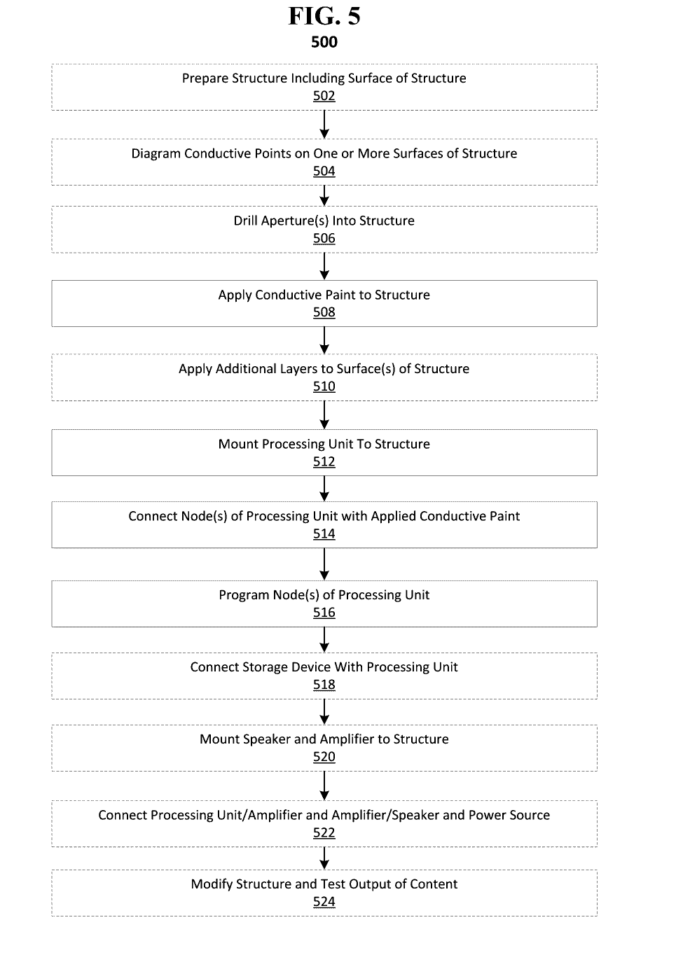

FIG. 5 illustrates an exemplary method 500 for producing a displayable device as described herein. One skilled in the art should recognize that the order of processing operations described in method 500 may not necessarily follow the order in which such operations are described herein.

Method 500 begins at operation 502 where one or more surfaces of a structure are prepared. An exemplary structure may be that described above. An exemplary structure may have one or more surfaces. Examples operations associated with operation 502 may comprise: unpacking materials, constructing portions of the structure, providing a usable surface such as a canvas/panel canvas, and applying a layer of primer to the surface, among other examples. In an example, operation 502 may comprise using a brush to spread one or more layers of primer across the surface. In some examples, operation 502 may be optional, for example in a case where a canvas comes pre-prepared.

Flow may proceed to operation 504, where conductive points are diagrammed on one or more surfaces of an exemplary structure. In examples, it may be useful to draft a layout of where portions of conductive paint may be applied. However, in other examples, operation 504 may be optional.

Flow may proceed to operation 506 where one or more sets of apertures may be drilled into one or more surfaces of the structure. As an example, an aperture may be provided in each area where a portion of conductive paint has been applied. In alternate examples of method 500, operation 506 may occur after substance is applied to a surface of an exemplary structure. In further examples, one or more apertures may be drilled to enhance output of signals from electrical components (e.g., speakers). However, in other examples, operation 506 may be optional if a surface/structure is pre-drilled.

Flow may proceed to operation 508 where conductive paint is applied to an exemplary structure. In examples, operation 508 may comprise applying conductive paint to one or more portions of at least one surface of a structure. Application (operation 508) of the conductive paint may comprise applying conductive paint to the pre-diagrammed portions laid out in operation 504. In other examples, operation 508 may comprise covering an entire surface with conductive paint. In some examples, flow may proceed to operation 510 where additional layers of substance are applied to surfaces of an exemplary structure. Examples of additional substances that may be applied to a surface are described throughout this description, for example, the description of FIG. 1A. In examples of operation 510, at least one of: a layer of primer, one or more layers of paint, and one or more layers of sealant may be applied to a surface of structure.

Flow may proceed to operation 512, where a processing unit is mounted to a portion of the structure. Examples of processing units, mounting, and interaction with other electrical components (including conductive paint) have been previously described. The processing unit may comprise one or more nodes, where electrical means (e.g., wires, etc.) may be used to contact one or more portions of the conductive paint. That is, operation 514 may comprise connecting one or more nodes of the processing unit with portions of the conductive paint. In examples, wiring may be connected to a node of the processing unit, for example, by soldering the wires to one or more connections/electrodes of the processing units. The wiring may be affixed to a portion of the structure, for example by any means including gluing, taping, stapling, etc. In some examples, operation 514 may comprise applying conductive paint to a wire. An end of a wire may be placed in contact with a portion of the conductive paint. In some examples, operation 514 may occur before the mounting operation 512.

One or more connected nodes of the processing unit may be programmed at operation 516. Programming of a processing unit is described above in previous examples. In some examples, flow may proceed to operation 518 where a storage device is connected with the processing unit. Examples of storage devices, processing units, connection, and interaction with other electrical components have been previously described.

In some examples where an interactive displayable device comprises additional electrical components, a speaker and an amplifier may be mounted to an exemplary structure in operation 520. Examples of speakers, amplifiers, mounting, and interaction with other electrical components (including a processing unit) have been previously described. Flow may proceed to operation 522 where electrical components are connected. In examples, one or more of a processing unit, amplifier and speaker may be connected. Additionally, one or more power sources may be connected to one or more electrical components as a power source to provide supply of power to an interactive displayable device. In some examples, operation 522 may comprise affixing an independent power source to the interactive displayable device that may provide power to the displayable device without requiring connection to another power source such as an outlet or processing device.

Flow may proceed to operation 524, where testing and/or modification may occur of the exemplary interactive displayable device. In examples, operation 524 may comprise testing output of content based on touch interaction. In some examples, operation 524 may further comprise modifying the structure of an exemplary interactive displayable device based on testing, for example. In other examples, operation 524 may comprise adding to a framework of an exemplary structure, for example by adding one or more additional surfaces for interactivity. As an example, another surface may be added, for example that may obscure view of electrical components. Similar processing operations as described above may be applied to transform the one or more additional surfaces into interactive surfaces.

In examples, the configuration of an exemplary interactive displayable device provides direct mapping to specific content output. That is, the environment in which an interactive displayable device operates is thought-out and programmatically configured to maximize out output and experience for an end user. The exemplary structure is configured such that electrical components are housed by structure and are self-contained within the structure. This configuration provide benefits over what is known as the configuration of the structure around the electrical components may create a unique environment that enables output to be channeled in a controlled manner, for example. As another benefit, exemplary devices disclosed herein may create an effect of reverberation of sound output that is not re-creatable by other known products. Other examples may also comprise adding of additional components and/or objects to further maximize, amplify or otherwise manipulate output of content such as audio, light, video, etc.

This disclosure described some aspects of the present technology with reference to the accompanying drawings, in which only some of the possible embodiments were shown. Other aspects may, however, be embodied in many different forms and should not be construed as limited to the embodiments set forth herein. Rather, these aspects were provided so that this disclosure was thorough and complete and fully conveyed the scope of the possible embodiments to those skilled in the art.

Although specific aspects were described herein, the scope of the technology is not limited to those specific embodiments. One skilled in the art will recognize other embodiments or improvements that are within the scope and spirit of the present technology. Therefore, the specific structure, acts, or media are disclosed only as illustrative embodiments. The scope of the technology is defined by the following claims and any equivalents therein.

What is claimed is:

1. A method comprising:
applying conductive paint to a structure that comprises one or more apertures, wherein the applying further comprises applying the conductive paint to at least one surface of the structure and within the one or more apertures;
mounting a processing unit to a portion of the structure;
connecting at least one node of the processing unit with the applied conductive paint; and
programming the node of the processing unit.

2. The method of claim 1, wherein the programming comprises setting the node to output content that is pre-programmed into the processing unit.

3. The method of claim 1, wherein the programming comprises connecting the processing unit to a processing device, and executing an application to program/re-program the node to output content.

4. The method of claim 1, wherein the programming comprises connecting the processing unit to a processing device, and executing an application to program the node to read content from a storage device.

5. The method of claim 4, further comprising connecting the storage device with the processing unit.

6. The method of claim 1, further comprising connecting the processing unit to a power source.

7. The method of claim 1, further comprising drilling the one or more apertures into the structure.

8. The method of claim 1, further comprising mounting a speaker and an amplifier to the structure, connecting the processing unit with the amplifier, and connecting the amplifier with the speaker.

9. The method of claim 8, further comprising connecting at least one of the processing unit, the amplifier and the speaker to a power source.

10. The method of claim 8, further comprising drilling a second set of apertures into the surface of the structure to enable passing of sound emittable from the speaker.

11. The method of claim 1, further comprising applying a layer of primer to the structure over the conductive paint.

12. The method of claim 11, further comprising applying, over the applied layer of primer, at least one from a group consisting of: at least one layer of paint and an object.

13. The method of claim 12, further comprising providing a layer of sealant over the layer of paint or the object.

14. The method of claim 1, wherein the connecting of the node with the conductive paint further comprises connecting at least one wire to the node of the processing unit and placing an end of the wire in contact with the conductive paint.

15. The method of claim 1, further comprising:
connecting another wire to a second node of the processing unit,
adding another surface to the structure, wherein the another surface covers the processing unit and has one or more apertures aligned with the another wire, and
applying the conductive paint to at least one portion of the another surface and within the one or more apertures to make contact with the another wire.

16. A device comprising:
a structure, wherein at least one portion of a first surface of the structure is covered with a layer of conductive paint and wherein the first surface has one or more apertures filled with the conductive paint; and
a programmed touch circuit board mounted on a second surface of the structure, wherein at least one wire places a node of the programmed touch circuit board in contact with the conductive paint.

17. The device according to claim 16, wherein the first surface of the structure is made of canvas and further comprises:
a layer of primer over the layer of conductive paint; and
another layer over the layer of primer, wherein the another layer is at least one from a group consisting of: a layer of paint and an object.

18. The device according to claim 17, wherein the first surface further comprises a layer of sealant over the additional layer.

19. The device according to claim 16, further comprising:
an amplifier mounted on the second surface of the structure, wherein the amplifier comprises a power source and the amplifier is connected with the programmed touch circuit board; and
a speaker mounted on the second surface of the structure, wherein the speaker is connected with the amplifier.

20. The device according to claim 19, further comprising: a storage device connected with the programmed touch circuit board, wherein the storage device stores content that is accessible by the programmed touch circuit board.

21. A device comprising:
a structure that comprises a first surface made of canvas, wherein at least one portion of the first surface is covered with a layer of conductive paint and wherein the first surface has a first set of one or more apertures filled with the conductive paint and a second set of one or more apertures;
a programmed processing unit mounted on a second surface of the structure, wherein at least one wire places a node of the programmed processing unit in contact with the conductive paint;
an amplifier mounted on the second surface of the structure, wherein the amplifier comprises a power source and the amplifier is connected with the programmed processing unit;
a speaker mounted on the second surface of the structure in alignment with the second set of one or more apertures, wherein the speaker is connected with the amplifier; and
storage device connected with the programmed processing unit, wherein the storage device stores content that is accessible by the programmed processing unit in response to touch input received at the portion of the first surface that is covered by the conductive paint.

22. The device according to claim 21, wherein the programmed processing unit is a programmed touch circuit board.

23. The device according to claim 21, wherein the structure further comprises:
at least a third surface covering the processing unit, the amplifier, and the speaker, wherein the third surface has one or more apertures aligned with another wire connected with a second node of the processing unit, and conductive paint is applied to at least one portion of the third surface including within the one or more apertures, and
wherein the conductive paint contacts the second wire.
